(19) United States
(12) Patent Application Publication
(10) Pub. No.: US 2014/0366940 A1
(43) Pub. Date: Dec. 18, 2014

(54) SOLAR CELL APPARATUS AND METHOD OF FABRICATING THE SAME

(71) Applicant: LG INNOTEK CO., LTD., Seoul (KR)

(72) Inventor: Chang Woo Kim, Seoul (KR)

(73) Assignee: LG INNOTECK CO., LTD., Seoul (KR)

(21) Appl. No.: 14/358,612

(22) PCT Filed: Nov. 15, 2012
(86) PCT No.: PCT/KR2012/009668

§ 371 Date: May 15, 2014

(30) Foreign Application Priority Data
Nov. 16, 2011 (KR) 10-2011-0119363

(51) Int. Cl. H01L 31/0224; H01L 31/032; H01L 31/072; H01L 31/0296

(52) U.S. Cl. CPC H01L 31/022425; H01L 31/02963; H01L 31/032; H01L 31/0322; H01L 31/072
USPC 136/256

(57) ABSTRACT

A solar cell apparatus according to the embodiment includes a support substrate; a barrier layer on the support substrate, the barrier layer including a compound of a material included in the support substrate; a back electrode layer on the barrier layer; a light absorbing layer on the back electrode layer; a buffer layer on the light absorbing layer; and a window layer on the buffer layer.

### TECHNICAL FIELD

The embodiment relates to a solar cell apparatus and a method of fabricating the same.

### BACKGROUND ART

Recently, as energy consumption is increased, solar cells to convert the solar light into electrical energy have been developed.

A solar cell (or photovoltaic cell) is a core element in solar power generation to directly convert solar light into electricity.

For example, if the solar light having energy greater than bandgap energy of a semi-conductor is incident into a solar cell having the PN junction structure, electron-hole pairs are generated. As electrons and holes are collected into an N layer and a P layer, respectively, due to the electric field formed in a PN junction part, photovoltage is generated between the N and P layers. In this case, if a load is connected to electrodes provided at both ends of the solar cell, current flows through the solar cell.

In particular, a CIGS-based solar cell, which is a PN hetero junction apparatus having a substrate structure including a glass substrate, a metallic back electrode layer, a P-type CIGS-based light absorbing layer, a high-resistance buffer layer, and an N-type window layer, has been extensively used.

Various studies and researches have been performed to improve electrical characteristics of the solar cell, such as low resistance and high transmittance.

When the substrate includes a metal, the metal included in the substrate may be diffused into the CIGS-based light absorbing layer, so that the efficiency of the solar cell may be decreased.

Although the above problem may be reduced by forming a barrier layer having a chemical formula, such as SiN and Al₂O₃, between the substrate and the light absorbing layer, since an additional process of forming the barrier layer is required, the productivity may be lowered, so the improvement is required.

### DISCLOSURE OF INVENTION

### Technical Problem

The embodiment provides a solar cell apparatus which can improve the reliability of devices by preventing degradation of the efficiency, which is caused when a metallic material included in a support substrate is diffused into a light absorbing layer, by forming a barrier layer on the support substrate.

### Solution to Problem

According to the embodiment, there is provided a solar cell apparatus including a support substrate; a barrier layer on the support substrate, the barrier layer including a compound of a material included in the support substrate; a back electrode layer on the barrier layer; a light absorbing layer on the back electrode layer; a buffer layer on the light absorbing layer; and a window layer on the buffer layer.

### Advantageous Effects of Invention

As described above, according to the solar cell apparatus of the embodiment, the barrier layer is formed on the support substrate having a metallic material so that efficiency degradation of the solar cell due to the diffusion of the metallic material of the support substrate into the light absorbing layer can be prevented. Thus, the device reliability may be improved.

### BRIEF DESCRIPTION OF DRAWINGS

FIG. 1 is a sectional view showing a solar cell apparatus according to the embodiment; and

FIGS. 2 to 5 are sectional views illustrating a procedure of fabricating a solar cell panel according to the embodiment.

### BEST MODE FOR CARRYING OUT THE INVENTION

In the description of the embodiments, it will be understood that when a substrate, a layer, a film or an electrode is referred to as being on or under another substrate, another layer, another film or another electrode, it can be directly or indirectly on the other substrate, the other layer, the other film, or the other electrode, or one or more intervening layers may also be present. Such a position of the layer has been described with reference to the drawings. The size of the elements shown in the drawings may be exaggerated for the purpose of explanation and may not utterly reflect the actual size.

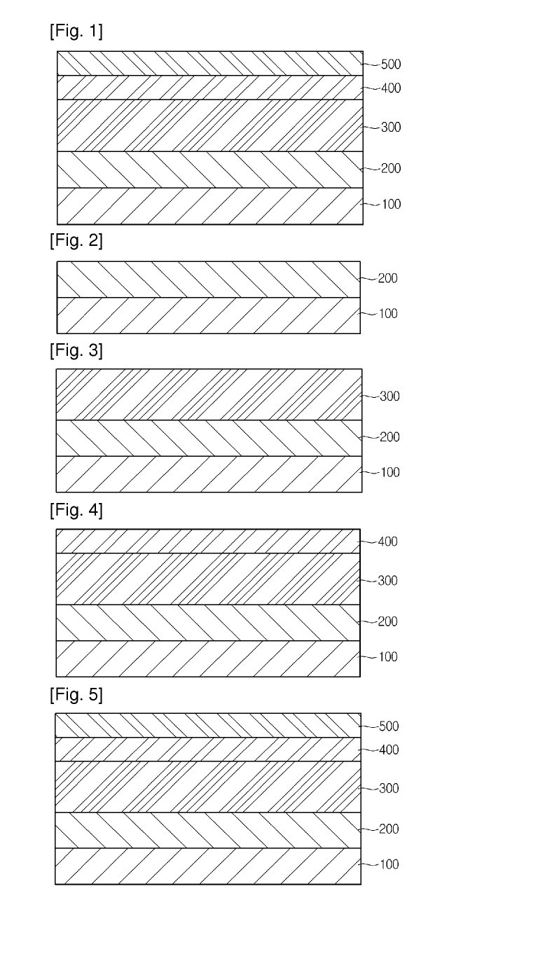

FIG. 1 is a sectional view showing a solar cell apparatus according to the embodiment. Referring to FIG. 1, the solar cell panel includes a support substrate 100, a barrier layer 200, a back electrode layer 300, a light absorbing layer 400, a buffer layer 500, and a window layer 600.

The support substrate 100 has a plate shape and supports the barrier layer 200, the back electrode layer 300, the light absorbing layer 400, the buffer layer 500, and the window layer 600.

The support substrate 100 may be an insulator. The support substrate 100 may be a metal substrate. In addition, the support substrate 100 may be formed of stainless steel (SUS, STS). The support substrate 100 may be identified with various symbols according to a component ratio of materials included in the support substrate 100 and may include at least one of C, Si, Mn, P, S, Ni, Cr, Mo and Fe. The support substrate 100 may be flexible.

The barrier layer 200 is formed on the support layer 100.

When the support substrate 100 includes a metal element, the material included in the support substrate may be diffused into the light absorbing layer, so that the photo-electric conversion efficiency may be reduced. Although the barrier layer of SiN or Al₂ O₃ may be formed to prevent the above, this requires an additional process. In addition,

In the embodiment, the barrier layer 200 including chemical compound of a material included in the substrate 100 may be formed on the surface of the substrate 100 including the metallic material through ion-nitriding.

According to the ion-nitriding, an inside of a sealed receptacle is depressurized at a pressure in the range of 1 Torr to 20 Torr and a direct current voltage in a range of 300 V to 1000 V is applied between a part which serves as a negative electrode (which is the support substrate 100 in the embodiment) and a receptacle wall which serves as a positive electrode in the mixed gas atmosphere of H₂ and N2, so that a glow discharge is generated between both electrodes. Thus, the N₂ gas is ionized into N⁺ and the N⁺ collides at a high speed with the support substrate 100. The kinetic energy of ions is converted into thermal energy, so that the support substrate 100 is heated at a temperature in the range of 800 to 1000 and simultaneously, the ions permeate into the surface of the substrate 100. Due to reaction of the collision, atoms such as Fe, C and O are emitted from the surface of the substrate 100. The Fe atoms are combined with N to form FeN and then, the FeN is attached onto the surface of the support substrate 100 so that the barrier layer 200 may be formed. Thus, the barrier layer 200 may have a chemical composition such as Fe₂N, Fe₃N and Fe₄N.

The ion-nitriding does not require a specific heating apparatus and represents the high nitriding rate. In addition, the thickness of the barrier layer 200 may be controlled by adjusting a temperature, a pressure and time. The barrier layer 200 according to the embodiment may have a thickness in the range of 0.8 to 1.2.

The barrier layer 200 may prevent the reduction of the photoelectric conversion efficiency caused by diffusing the metallic material (Fe) included in the support substrate 100 into the light absorbing layer 400.

The back electrode layer 300 is provided on the barrier layer 200. The back electrode layer 300 is a conductive layer. The back electrode layer 300 transfers charges produced in the light absorbing layer 400 of the solar cell, thereby allowing current to flow to the outside of the solar cell. The back electrode layer 300 must represent higher electric conductivity and lower resistivity in order to perform the above function.

In addition, the back electrode layer 300 must maintain high-temperature stability when heat treatment is performed under the atmosphere of sulfur (S) or selenium (Se) required when a CIGS compound is formed. In addition, the back electrode layer 300 must represent a superior adhesive property with respect to the substrate 100 such that the back electrode layer 300 is prevented from being delaminated from the substrate 100 due to the difference in the thermal expansion coefficient between the back electrode layer 300 and the substrate 100.

The back electrode layer 300 may include any one of molybdenum (Mo), gold (Au), aluminum (Al), chrome (Cr), tungsten (W), and copper (Cu). Among them, Mo makes the lower difference in the thermal expansion coefficient from the substrate 100 when comparing with the other elements, so that the Mo represents a superior adhesive property, thereby preventing the above de-lamination phenomenon, and totally satisfying the characteristic required for the back electrode layer 300. The back electrode layer 300 may have a thickness in the range of 400 to 1000.

The light absorbing layer 400 may be formed on the back electrode layer 300. The light absorbing layer 400 includes a P-type semiconductor compound. In more detail, the light absorbing layer 400 includes a group I-III-VI-based compound. For example, the light absorbing layer 400 may have a Cu(In,Ga)Se₂ (CIGS) crystal structure, a Cu(In)Se₂ crystal structure, or a Cu(Ga)Se2 crystal structure. The light absorbing layer 400 may have an energy bandgap in the range of 1.1 eV to 1.2 eV, and a thickness in the range of 1.5 to 2.5.

The buffer layer 500 is provided on the light absorbing layer 400. According to the solar cell having the light absorbing layer 300 including the CIGS compound, a P—N junction is formed between a CIGS compound thin film, which serves as a P-type semiconductor, and the window layer 600 which is an N-type semiconductor. However, since two materials represent the great difference in the lattice constant and the bandgap energy therebetween, a buffer layer having the intermediate bandgap between the bandgaps of the two materials is required to form the superior junction between the two materials.

The material used for forming the buffer layer 500 includes CdS and ZnS. Since the

CdS is relatively superior to any other materials in the aspect of the solar cell generation efficiency, the CdS has been generally used. The buffer layer 500 may be formed at a thickness in the range of 50 to 80.

The high-resistance buffer layer (not shown) may be disposed on the buffer layer 500. The high-resistance buffer layer may include i-ZnO, which is zinc oxide not doped with impurities. The high-resistance buffer layer may have an energy bandgap in the range of about 3.1 eV to about 3.3 eV and a thickness in the range of 50 to 60.

The window layer 600 is disposed on the buffer layer 500. The window layer 600 is transparent and a conductive layer. The resistance of the window layer 600 is higher than that of the back electrode layer 300.

The window layer 600 includes oxide. For example, the window layer 600 may include zinc oxide, indium tin oxide (ITO), or indium zinc oxide (IZO). In addition, the window layer 600 may include Al doped zinc oxide (AZO) or Ga doped zinc oxide (GZO). The window layer 600 may be formed at a thickness in the range of 800 to 1000.

According to the solar cell apparatus of the embodiment, the barrier layer is formed on the support substrate having a metallic material so that efficiency degradation of the solar cell due to the diffusion of the metallic material of the support substrate into the light absorbing layer can be prevented. Thus, the device reliability may be improved.

FIGS. 2 to 5 are sectional views illustrating the method of fabricating the solar cell according to the embodiment. The description about the method of fabricating the solar cell will be made based on the above description about the solar cell apparatus. The description about the solar cell apparatus may be essentially incorporated herein by reference.

Referring to FIG. 2, the barrier layer 200 is formed on the support substrate 100. The barrier layer 200 may be formed by depressurizing an internal pressure of a sealed receptacle in the range of 1 Torr to 20 Torr at a temperature in the range of 800 to 1000 while applying a direct current voltage in a range of 300 V to 1000 V between the support substrate 100 which serves as a negative electrode and the receptacle wall which serves as a positive electrode in the mixed gas atmosphere of H₂ and N2.

Referring to FIG. 3, the back electrode layer 300 is formed on the barrier layer 200. The back electrode layer 300 may be formed by depositing Mo. The back electrode layer 300 may be formed through a sputtering scheme. In addition, an additional layer such as an anti-diffusion layer may be interposed between the support substrate 100 and the back electrode layer 300.

Referring to FIG. 4, the light absorbing layer 400 is formed on the back electrode layer 300. The light absorbing layer 400 is formed by extensively using schemes, such as a scheme of forming a Cu(In,Ga)Se₂(CIGS) based-light absorbing layer 400 by simultaneously or separately evaporating Cu, In, Ga, and Se and a scheme of performing a selenization process after a metallic precursor film has been formed.

To the contrary, the sputtering process and the selenization process of using targets of Cu, In and Ga may be simultaneously performed. The CIS or CIG based light absorbing layer 400 may be formed through the sputtering process and the selenization process using only the Cu and In targets or the Cu and Ga targets.

Referring to FIG. 5, the light absorbing layer 400 is formed on the buffer layer 500. The buffer layer 500 may have the chemical composition of CdS and may be formed through PVD (Physical Vapor Deposition) or MOCVD (Metal-Organic Chemical Vapor Deposition), but the embodiment is not limited thereto.

Then, the window layer 600 is formed on the buffer layer 500. The window layer 600 may be formed on the buffer layer 500 by depositing a transparent conductive material such as Al doped zinc oxide (AZO) through a sputtering scheme.

Any reference in this specification to one embodiment, an embodiment, example embodiment, etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effects such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

1. A solar cell apparatus comprising:
a support substrate;
a barrier layer on the support substrate, the barrier layer including a compound of a material included in the support substrate;
a back electrode layer on the barrier layer;
a light absorbing layer on the back electrode layer;
a buffer layer on the light absorbing layer; and
a window layer on the buffer layer.

2. The solar cell apparatus of claim 1, wherein the barrier layer has a thickness in a range of 0.8 μm to 1.2 μm.

3. The solar cell apparatus of claim 1, wherein the barrier layer has a chemical composition including at least one of Fe₂N, Fe₃N or Fe₄N.

4. The solar cell apparatus of claim 1, wherein the support substrate includes at least one of C, Si, Mn, P, S, Ni, Cr, Mo or Fe.

5-13. (canceled)

14. The solar cell apparatus of claim 1, wherein the barrier layer comprises an ion-nitriding metallic material.

15. The solar cell apparatus of claim 1, the back electrode layer comprises at least one of molybdenum, gold , aluminum, chrome, tungsten or copper.

16. The solar cell apparatus of claim 1, wherein the window layer is a transparent conductive layer.

17. The solar cell apparatus of claim 1, wherein a resistance of the window layer is higher than that of the back electrode layer.

18. The solar cell apparatus of claim 1, wherein the window layer comprises an oxide material.

19. The solar cell apparatus of claim 18, wherein the window layer includes at least one of Zinc oxide, Indium tin oxide , or Indium zinc oxide, Al doped zinc oxide or Ga doped zinc oxide.

20. The solar cell apparatus of claim 1, wherein a thickness of the window layer 600 is in the range of 800 nm to 1000 nm.

21. The solar cell apparatus of claim 1, further comprising a second buffer layer on the buffer layer, and
wherein the second buffer layer has a higher resistance than the buffer layer.

22. The solar cell apparatus of claim 21, wherein the second buffer layer comprises zinc oxide not doped with impurities.

23. The solar cell apparatus of claim 21, wherein the second buffer layer has an energy bandgap in the range of about 3.1 eV to about 3.3 eV.

24. The solar cell apparatus of claim 21, wherein the second buffer layer has a thickness in the range of about 50 nm about 60 nm.
